(19) United States
(12) Patent Application Publication
(10) Pub. No.: US 2026/0033196 A1
(43) Pub. Date: Jan. 29, 2026

(54) DISPLAY PANEL AND DISPLAY DEVICE

(71) Applicant: HKC CORPORATION LIMITED, SHENZHEN (CN)

(72) Inventors: Xiaoxiao YUAN, SHENZHEN (CN); Chuan WU, SHENZHEN (CN); Zhonglin CAO, SHENZHEN (CN); Dongmei WEI, SHENZHEN (CN); Jie CHEN, SHENZHEN (CN); Fengzhen DANG, SHENZHEN (CN); Yao LI, SHENZHEN (CN); Wenyu YI, SHENZHEN (CN); Lidan YE, SHENZHEN (CN)

(73) Assignee: HKC CORPORATION LIMITED, SHENZHEN (CN)

(21) Appl. No.: 19/262,946

(22) Filed: Jul. 8, 2025

(30) Foreign Application Priority Data
Jul. 23, 2024 (CN) 202410997173.9

(51) Int. Cl. H10K 59/131; H10K 59/122; H10K 59/127; H10K 59/35

(52) U.S. Cl. CPC H10K 59/1315; H10K 59/122; H10K 59/1275; H10K 59/352

(57) ABSTRACT

Disclosed is display panel and a display device. By electrically connecting each of the isolation structures to the cathode layers of the corresponding sub-pixels, the conductive portions and the cathode layers collectively form a unified full-area cathode. Connecting the conductive portions to the silicon-based driving substrate not only increases thickness of the conductive portions to reduce connection resistance between the cathode layers of adjacent sub-pixels, thereby reducing resistance of the unified full-area cathode and mitigating voltage drop, but also shortens a transmission path of cathode signals by connecting at least a part of the cathode layers to the silicon-based driving substrate through the corresponding conductive portions, further reducing voltage drop and enhancing display performance of the display panel.

### CROSS REFERENCE TO RELATED DISCLOSURES

The present disclosure claims priority to Chinese Patent Application No. 2024109971739, files on Jul. 23, 2024, the contents of which are herein incorporated by reference in their entirety.

### TECHNICAL FIELD

The present disclosure relates to but not limited to a field of display technologies, and in particular to a display panel and a display device.

### BACKGROUND

Compared with traditional Active-Matrix Organic Light-Emitting Diode (AMOLED) display technology, silicon-based Organic Light-Emitting Diode (OLED) micro-displays use single-crystal silicon chips as substrates and leverage mature Complementary Metal Oxide Semiconductor (CMOS) processes to achieve a smaller pixel size and higher integration. This enables near-eye display products comparable to large-screen displays, making the silicon-based OLED micro-displays highly promising.

However, during the evaporation process for sub-pixels, the silicon-based driving circuit layer is prone to damage.

### SUMMARY

According to a first aspect of the present disclosure, a display panel is provided, the display panel includes a silicon-based driving substrate and a light-emitting carrier plate bonded to the silicon-based driving substrate; the light-emitting carrier plate includes a glass substrate, a pixel-defining layer, a plurality of sub-pixels, and a plurality of isolation structures; the glass substrate has a plurality of cathode through holes; the pixel-defining layer is disposed on a side of the glass substrate away from the silicon-based driving substrate, and the pixel-defining layer has a plurality of pixel openings and a plurality of connection through holes; each of the sub-pixels is disposed in the pixel opening, and each of the sub-pixels includes an anode layer, a light-emitting layer, and a cathode layer sequentially stacked; the isolation structures are protruding from the pixel-defining layer, each of the isolation structures is disposed on a side of the sub-pixel, and each of the isolation structures includes a conductive portion and a top structure sequentially stacked, and the cathode layer of each of the sub-pixels is lapped onto the conductive portion of a corresponding one of the isolation structures such that cathode layers of the sub-pixels are electrically connected together with each other; and conductive portions of at least a part of the isolation structures are electrically connected to the silicon-based driving substrate through corresponding connection through holes and cathode through holes.

According to a second aspect of the present disclosure, a display device is provided, the display panel includes a mainboard and a display panel, the display panel includes a silicon-based driving substrate and a light-emitting carrier plate bonded to the silicon-based driving substrate; the light-emitting carrier plate includes a glass substrate, a pixel-defining layer, a plurality of sub-pixels, and a plurality of isolation structures; the glass substrate has a plurality of cathode through holes; the pixel-defining layer is disposed on a side of the glass substrate away from the silicon-based driving substrate, and the pixel-defining layer has a plurality of pixel openings and a plurality of connection through holes; each of the sub-pixels is disposed in the pixel opening, and each of the sub-pixels includes an anode layer, a light-emitting layer, and a cathode layer sequentially stacked; the isolation structures are protruding from the pixel-defining layer, each of the isolation structures is disposed on a side of the sub-pixel, and each of the isolation structures includes a conductive portion and a top structure sequentially stacked, and the cathode layer of each of the sub-pixels is lapped onto the conductive portion of a corresponding one of the isolation structures such that cathode layers of the sub-pixels are electrically connected together with each other; and conductive portions of at least a part of the isolation structures are electrically connected to the silicon-based driving substrate through corresponding connection through holes and cathode through holes.

### BRIEF DESCRIPTION OF THE DRAWINGS

In order to more clearly illustrate the technical solutions in the embodiments of the present disclosure, the following briefly describes the accompanying drawings used in the embodiments. It is apparent that the drawings in the following description are only some embodiments of the present disclosure. For persons of ordinary skill in the art, other drawings may be derived from these drawings without creative effort.

FIG. 1 is a structural schematic diagram of an embodiment of a display panel provided by the present disclosure.

FIG. 2 is a layout schematic diagram of sub-pixels and connection through holes provided by a first embodiment of the present disclosure.

FIG. 3 is a layout schematic diagram of sub-pixels and connection through holes provided by a second embodiment of the present disclosure.

FIG. 4 is a layout schematic diagram of sub-pixels and connection through holes provided by a third embodiment of the present disclosure.

FIG. 5 is a layout schematic diagram of sub-pixels and connection through holes provided by a fourth embodiment of the present disclosure.

FIG. 6 is a layout schematic diagram of sub-pixels and connection through holes provided by a fifth embodiment of the present disclosure.

FIG. 7 is a layout schematic diagram of sub-pixels and connection through holes provided by a sixth embodiment of the present disclosure.

FIG. 8 is a structural schematic diagram of an embodiment of a display device provided by the present disclosure.

### REFERENCE NUMERALS IN THE DRAWINGS

display panel 100, light-emitting carrier plate 10, glass substrate 11, cathode through hole 111, anode through hole 112, pixel-defining layer 12, pixel opening 121, connection through hole 122, sub-pixel 13, anode layer 131, light-emitting layer 132, cathode layer 133, isolation structure 14, conductive portion 141, top structure 142, support structure 142A, eave structure 142B, expansion electrode 15, cathode expansion electrode 151, anode expansion electrode 152, encapsulation layer 16, first encapsulation layer 161, second encapsulation layer 162, silicon-based driving substrate 20, silicon substrate 21, driving circuit layer 22, cathode driving electrode 221, anode driving electrode 222, mainboard 200, display device 300.

### DETAILED DESCRIPTION

The technical solutions in the embodiments of the present disclosure will be described in detail below with reference to the accompanying drawings.

In the following description, specific details such as system architectures, interfaces, and techniques are provided for illustrative purposes only, not to limit the scope of the disclosure.

In order to make the purpose, technical solutions and advantages of the present disclosure clearer, the following will be described in further detail in conjunction with drawings, the described embodiments should not be regarded as a limitation of the present disclosure, for those skilled in the art, other drawings may be acquired according to the drawings without any creative work.

A term “embodiment” in the following description describes a subset of all possible embodiments, but it is understood that “embodiment” may be the same subset or a different subset of all possible embodiments, and may be combined with each other without conflict.

In the following description, terms “first/second/third” are used only to distinguish similar objects and do not represent a specific order for the objects, and it is understood that the terms “first/second/third” may be interchanged in a specific order or sequence so that the embodiments of the present disclosure described can be implemented in an order other than the order or sequence described in the drawings and specification. The terms “first”, “second” and “third” in this disclosure are used for descriptive purposes only and are not to be construed as indicating or implying relative importance or as implicitly indicating the quantity of the technical features indicated. Thus, a feature defined as “first”, “second”, or “third” may explicitly or implicitly include at least one of the features. In the description of this disclosure, “multiple” means at least two, such as two, three, etc., unless otherwise expressly specified. All directional indications in the embodiments of this disclosure (e.g. up, down, left, right, front, back . . . ) are only used to explain the relative position relationship and motion between the components in a specific attitude (as shown in the drawings). When the specific attitude changes, the directional indication may also change accordingly. Furthermore, the terms “including” and “having”, and any variation thereof, are intended to cover non-exclusive inclusion. For example, a process, method, system, product or device including a series of steps or units is not limited to the listed steps or units, but optionally also includes steps or units not listed, or optionally includes other steps or units inherent to those processes, methods, products or devices.

Unless otherwise defined, all technical and scientific terms used herein have same meaning as commonly understood by those skilled in the art belonging to the present disclosure. The terms used herein are for the purpose of describing embodiments of the present disclosure only and are not intended to limit the present disclosure.

Please refer to FIG. 1, FIG. 1 is a structural schematic diagram of an embodiment of a display panel provided by the present disclosure.

The present disclosure provides a display panel 100. The display panel 100 includes a silicon-based driving substrate 20 and a light-emitting carrier plate 10. The light-emitting carrier plate 10 is bonded to the silicon-based driving substrate 20. The light-emitting carrier plate 10 includes a glass substrate 11, a pixel-defining layer 12, a plurality of sub-pixels 13, and a plurality of isolation structures 14. The glass substrate 11 has a plurality of cathode through holes 111. The pixel-defining layer 12 is disposed on a side of the glass substrate 11 away from the silicon-based driving substrate 20. The pixel-defining layer 12 has a plurality of pixel openings 121 and a plurality of connection through holes 122. Each of the sub-pixels 13 is disposed in the pixel opening 121. Each of the sub-pixel 13 includes an anode layer 131, a light-emitting layer 132, and a cathode layer 133 sequentially stacked. Each of the isolation structures 14 protrudes from the pixel-defining layer 12 and is disposed on a side of corresponding one of the sub-pixels 13. Each of the isolation structures 14 includes a conductive portion 141 and a top structure 142 sequentially stacked. The cathode layer 133 of each of the sub-pixels is lapped onto the conductive portion 141 of a corresponding one of the isolation structures such that cathode layers 133 of the sub-pixels are electrically connected together with each other. Conductive portions 141 of at least a part of the isolation structures 14 are electrically connected to the silicon-based driving substrate 20 through corresponding connection through holes 122 and cathode through holes 111.

By separately fabricating the light-emitting carrier plate 10 with the sub-pixels 13 and bonding the sub-pixels 13 to the silicon-based driving substrate 20, the sub-pixels 13 are not directly fabricated on the silicon-based driving substrate 20. This reduces the impact of the sub-pixel evaporation process on a driving circuit layer 22 of the silicon-based driving substrate 20, thereby minimizing losses caused by subsequent process errors and lowering the manufacturing cost of the silicon-based driving substrate 20. By electrically connecting each of the isolation structures 14 to the cathode layers 133 of the corresponding sub-pixels 13, the conductive portions 141 and the cathode layers 133 collectively form a unified full-area cathode. Connecting the conductive portions 141 to the silicon-based driving substrate 20 not only increases thickness of the conductive portions 141 to reduce connection resistance between the cathode layers 133 of adjacent sub-pixels 13, thereby reducing resistance of the unified full-area cathode and mitigating voltage drop, but also shortens a transmission path of cathode signals by connecting at least a part of the cathode layers 133 to the silicon-based driving substrate 20 through the corresponding conductive portions 141, further reducing voltage drop and enhancing display performance of the display panel 100.

The silicon-based driving substrate 20 may include a silicon substrate 21 and a driving circuit layer 22. The driving circuit layer 22 may be disposed on a side of the silicon substrate 21 close to the light-emitting carrier plate 10. The silicon substrate 21 may be a substrate made of single-crystal silicon. The driving circuit layer 22 may include an active driving circuit (not shown) integrated on the silicon substrate 21 using CMOS processes.

Separating the fabrication of the silicon-based driving substrate 20 and the light-emitting carrier plate 10 improves production efficiency, avoids damage to the silicon-based driving substrate 20 during evaporation, and reduces the loss of the silicon-based driving substrate 20. That is to say, from a process perspective, fabricating the silicon-based driver substrate 20 and the light-emitting carrier substrate 10 separately not only improves the yield but also reduces the cost.

The glass substrate 11 may further include a plurality of anode through holes 112 and each of the anode through holes 112 is spaced apart from a corresponding one of the cathode through holes 111 with a distance. Each anode layer 131 may be electrically connected to the silicon-based driving substrate 20 through a corresponding one of the anode through holes 112. Both the cathode through holes 111 and anode through holes 112 may be formed using Through-Glass Via (TGV) technology.

It should be understood that the TGV technology has the advantages of superior high-frequency electrical properties, low cost, simple process flow and strong mechanical stability compared with Through-Silicon Via (TSV) technology.

Compared to conventional techniques where the sub-pixels 13 are fabricated on the silicon-based driving substrate 20 and each of the sub-pixels 13 is electrically connected to the silicon-based driving substrate 20 through a corresponding silicon through hole, the sub-pixels 13 are disposed on the glass substrate 11 and each of the sub-pixels 13 is bonded to the silicon-based driving substrate 20 through a corresponding glass through hole in the present disclosure, the costs are reduced and high-frequency electrical performance is improved.

Each of the anode through hole 112 may be disposed in a one-to-one correspondence with a corresponding anode layer 131 and disposed adjacent to a corresponding one of the cathode through holes 111, ensuring each of the anode through hole 112 being as close as possible to a corresponding one of the isolation structures 14 and as far away as possible from a corresponding one of the pixel openings 121, which is beneficial for the flattening of the anode layer 131.

The material of the pixel-defining layer 12 is not limited and can be selected based on actual requirements. Each of the connection through hole 122 may be spaced apart from a corresponding one of the anode layers 131 in a direction parallel to the pixel-defining layer 12 and penetrate the pixel-defining layer 12 in a direction perpendicular to the pixel-defining layer 12.

The conductive material in the connection through holes 122 may be the same as or different from that of the conductive portions 141. The conductive material in the connection through holes 122 is not limited and may be selected according to actual scenarios. The connection through holes 122 may be a plated through hole (PTH) and may be used to connect the each of the conductive portions 141 to a corresponding one of the cathode through holes 111.

In this embodiment, the conductive material in the connection through holes 122 is different from that of the conductive portions 141.

The isolation structures 14 may be used to isolate sub-pixels 13 of different colors to prevent optical crosstalk. Compared with the existing technologies that adopt the FMM (Fine Metal Mask) process to fabricate the sub-pixels 13, in this embodiment, a design of isolating the sub-pixels 13 with the isolation structures 14 is adopted, which eliminates the need for a fine metal mask and may reduce costs.

In this embodiment, the isolation structures 14 may be located between sub-pixels 13 of different colors and also between sub-pixels 13 of the same color.

Noted that the display panel 100 provided by the present disclosure may include a display region (not shown) and a bezel region (not shown), the sub-pixels 13 and the isolation structures 14 may be located in the display region.

In a direction parallel to the glass substrate 11, the top structure 142 of each of the isolation structures may extend beyond a corresponding one of the conductive portions 141. An orthographic projection of each of the top structures 142 on the pixel-defining layer 12 may cover that of a corresponding one of the conductive portions 141 and be larger in area.

The orthographic projection of each of the top structures 142 on the glass substrate 11 may cover that of the corresponding one of the cathode through holes 111 to ensure that each of the cathode through holes 111 is not overlapped with the anode layer 131 of a corresponding one of the sub-pixels.

Each of the top structures 142 of the isolation structures 14 may include a support structure 142A and an eave structure 142B. The support structure 142A of each of the top structures may be disposed on an upper surface of the conductive portion 141 of a corresponding one of the isolation structures 14 and support the eave structure 142B of the corresponding one of the isolation structures. An edge of a portion of the eave structure 142B of each top structures 12 extending beyond the conductive portion 141 of the corresponding one of the top structures 142 may be configured to control the evaporation angle of a corresponding one of the sub-pixels 13, enabling the cathode layer 133 of each of the sub-pixels 13 to fully cover the light-emitting layer 132 of each of the sub-pixels 13 and form a stable electrical contact with the corresponding one of the conductive portions 141.

The eave structure 142B of each of the top structures 142 may extend beyond the upper surface of the support structure 142A of the corresponding one of the top structures 142 in a direction parallel to the pixel-defining layer 12. By arranging the support structure 142A, the thickness of the portion of the conductive portion 141 of each of the isolation structures 14 protruding from the pixel-defining layer 12 may be reduced, thereby preventing the opaque conductive portion 141 of each isolation structures 14 from blocking lateral light emitted by the sub-pixels 13 and improving light utilization efficiency of the sub-pixels 13. Additionally, this configuration facilitates the cathode layer 133 of each of the sub-pixels 13 to climb over the conductive portion 141 of a corresponding one of the isolation structures 14, enabling robust electrical contact therewith.

It should be understood that the cathode layer 133 of each of the sub-pixels 13 is disposed on the side of the conductive portion 141 of a corresponding one of the isolation structures 14 away from the glass substrate 11. A portion of the cathode layer 133 of each of the sub-pixels 13 may be lapped onto the upper surface of the conductive portion 141 of the corresponding one of the isolation structures 14 to establish electrical connection therebetween.

The conductive portion 141 of each of the isolation structures 14 may protrude above the upper surface of the pixel-defining layer 12. The conductive portion 141 of each of the isolation structures 14 may be lapped onto the cathode layer 133 of the corresponding one of the sub-pixels 13, enabling mutual interconnection of the cathode layers 133 across adjacent sub-pixels 13, and ultimately forming the unified full-area cathode.

The conductive portion 141 of each of the isolation structures 14 may cover a corresponding one of the connection through holes 122, so as to prevent the corresponding connection through hole 122 from short-circuiting with the anode layer 131 of a corresponding one of the sub-pixels 13 caused by excessive spatial occupation of the corresponding connection through hole 122 between adjacent sub-pixels 13.

The conductive portions 141 of at least a part of the isolation structures 14 may be electrically connected with the silicon-based driving substrate 20 through corresponding connection through holes 122 and the cathode through holes 111 sequentially. That is, the corresponding connection through holes 122 may be provided directly beneath the conductive portions 141 of a part of the isolation structures 14, while no connection through hole 122 is provided directly beneath the conductive portions 141 of other part of the isolation structures 14; alternatively, the connection through holes 122 may be provided beneath conductive portions 141 of all of the isolation structures 14. The conductive portion 141 of each of the isolation structures 14 may be in contact with the corresponding connection through hole 122 arranged directly beneath it to achieve electrical interconnection.

In some embodiments, a single one of the isolation structures 14 may be arranged corresponding to at least a corresponding one of the connection through holes 122. That is, among the isolation structures 14 electrically connected to the silicon-based driving substrate 20 through the connection through holes 122, the conductive portion 141 of one isolation structure 14 may cover at least one connection through hole 122. In other words, one isolation structure 14 may be electrically connected to the silicon-based driving substrate 20 through one or more corresponding connection through holes 122. The greater the number of connection through holes 122, the lower the connection resistance between the cathode layers 133 of adjacent sub-pixels 13, thereby improving the voltage drop mitigation effect.

In other embodiments, some of the isolation structures 14 share a same one of the connection through holes 122. That is to say, among the isolation structures 14 that are electrically connected to the silicon-based driving substrate 20 through the corresponding connection through holes 122, the conductive portions 141 of some of the isolation structures 14 cover the same one of the connection through holes 122. By allowing the some of the isolation structures 14 to share the same one of the connection through holes 122, the aperture of the connection through holes 122 may be appropriately increased, which simplifies the manufacturing of the connection through holes 122 and is beneficial to improving product yield. Some of the isolation structures 14 may be partially overlapped with each other and have a common overlapping region. The same one of the connection through holes 122 may be disposed in the overlapping region.

It should be understood that when some of the isolation structures 14 share the same one of the connection through holes 122, the adjustable range of the aperture of the connection through holes 122 may be related to the arrangement of the sub-pixels 13 and the distance between the sub-pixels 13.

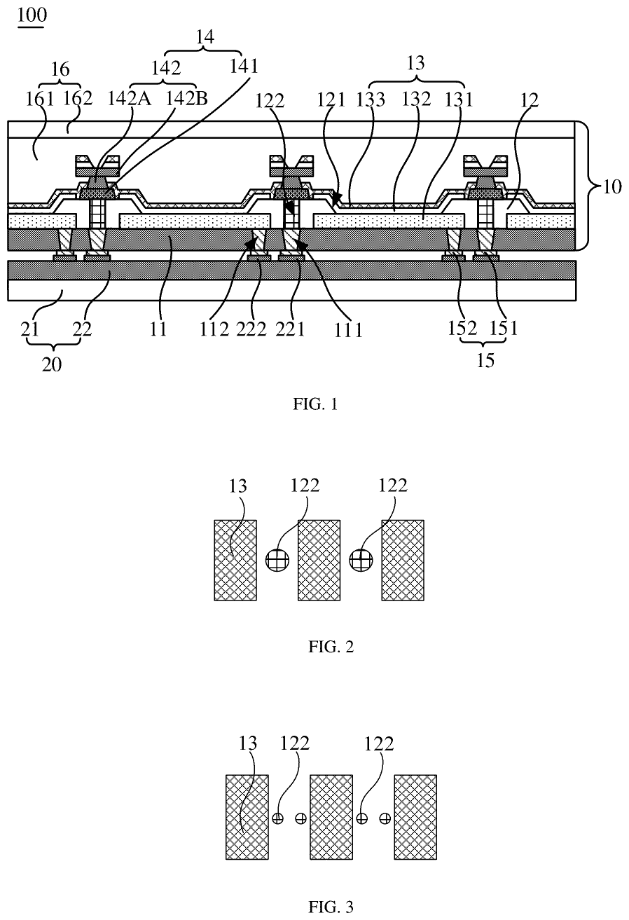

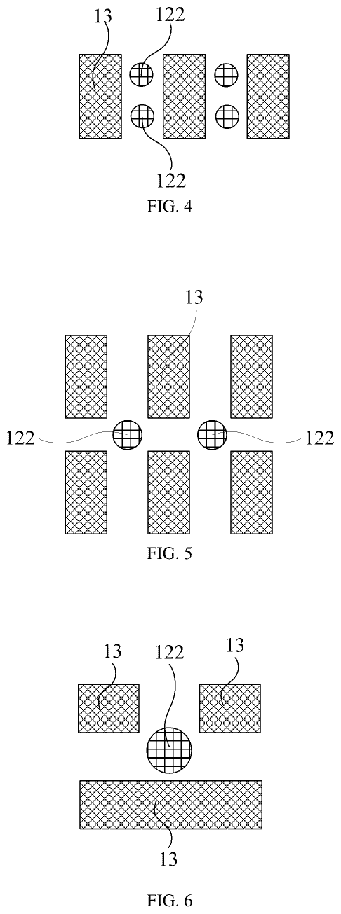

Please refer to FIG. 1 to FIG. 4, FIG. 2 is a layout schematic diagram of sub-pixels and connection through holes provided by a first embodiment of the present disclosure. FIG. 3 is a layout schematic diagram of sub-pixels and connection through holes provided by a second embodiment of the present disclosure. FIG. 4 is a layout schematic diagram of a sub-pixels and connection through holes provided by a third embodiment of the present disclosure.

In this embodiment, a single one of the isolation structures 14 may be disposed corresponding to a corresponding one of the connection through holes 122.

In a direction parallel to the glass substrate 11, the cross-sections of the connection through holes 122 may be in shapes such as a rectangle, a circle, a triangle or a polygon, etc. The cross-sections of the connection through holes 122 are not limited here and may be selected according to actual needs.

In this embodiment, in the direction parallel to the glass substrate 11, the cross-sections of the connection through holes 122 may be circular, which facilitate the preparation of the connection through holes 122.

In some embodiments, the aperture of the connection through holes 122 may be 5 microns to 15 microns. It should be understood that in other embodiments, the aperture of the connection through holes 122 may be adjusted according to the spacing between the sub-pixels 13 and the arrangement of the sub-pixels 13, and may be adjusted to other values.

The display panel 100 provided by the embodiments of the present disclosure may include sub-pixels 13 of various colors. A single one of the sub-pixels 13 may be disposed corresponding to a single one of the pixel openings 121. The sub-pixels 13 may be an OLED. The color of the sub-pixels 13 is not limited here and may be selected according to actual needs.

In some embodiments, the size of the sub-pixels 13 may be 6 microns to 15 microns. It should be understood that the size of the sub-pixels 13 may also be other values.

In some embodiments, in the direction parallel to the glass substrate 11, the sub-pixels 13 may be rectangular. Each of the connection through holes 122 may be located on a side of a rectangle of a corresponding one of the sub-pixels; alternatively, each of the connection through holes 122 may be located at a corner of the rectangle of a corresponding one of the sub-pixels; alternatively, each of a part of the connection through holes 122 may be located on the side of the rectangle of a corresponding one of the sub-pixels, and each of another part of the connection through holes 122 may be located at a corner of the rectangle of another corresponding one of the sub-pixels.

In this embodiment, each of the connection through holes 122 may be located on a long side of the rectangle of the corresponding one of the sub-pixels and between two adjacent sub-pixels 13.

In some embodiments, the aperture of the connection through holes 122 may be 10 microns.

In other embodiments, each of the connection through holes 122 may be located on a short side of the rectangle of the corresponding one of the sub-pixels; alternatively, each of the connection through hole 122 may be located on each side of the rectangle of the corresponding one of the sub-pixels. A single one of the isolation structures 14 may correspond to two connection through holes 122, and the two connection through holes 122 may be arranged on a side of the rectangle of a corresponding one of the sub-pixels and arranged side by side along the long side or short side of the rectangle of the corresponding one of the sub-pixels (see FIG. 3 and FIG. 4).

It should be understood that when a single one of the isolation structures 14 is arranged corresponding to the plurality of connection through holes 122, and the plurality of connection through holes 122 are located on the same side of the rectangle of the corresponding one of the sub-pixels, the aperture of the connection through holes 122 may be appropriately reduced to avoid occupying a region of the corresponding sub-pixels as much as possible.

The light-emitting carrier plate 10 may further include a plurality of expansion electrodes 15. Each of the expansion electrodes 15 may be located on a side of the glass substrate 11 away from a corresponding one of the isolation structures 14. Each of the expansion electrodes 15 may include an anode expansion electrode 152 and a cathode expansion electrode 151.

Each of the conductive portions 141 may be electrically connected to the cathode expansion electrode 151 of a corresponding one of the expansion electrodes 15 through a corresponding connection through hole 122 and a corresponding cathode through hole 111 in sequence, the cathode expansion electrode 151 of each of the expansion electrodes 15 may be bonded to a corresponding one of cathode driving electrodes 221 of the silicon-based driving substrate 20.

The anode layer 131 of each of the sub-pixels may be electrically connected to the anode expansion electrode 152 of a corresponding one of the expansion electrodes 15 through a corresponding one of the anode through holes 112. The anode expansion electrode 152 of each of the expansion electrodes 15 may be bonded to a corresponding one of anode driving electrodes 222 of the silicon-based driving substrate 20.

The driving circuit layer 22 may have the cathode driving electrode 221 and the anode driving electrode 222. That is, the cathode expansion electrode 151 of each of the expansion electrodes 15 may be bonded to a corresponding one of the cathode driving electrodes 221 of the driving circuit layer 22. The anode expansion electrode 152 may be bonded to a corresponding one of the anode driving electrodes 222 of the driving circuit layer 22.

That is to say, the expansion electrodes 15 on the light-emitting carrier plate 10 may be correspondingly bonded to a corresponding driving electrode (i.e., the corresponding anode driving electrode 222 and the corresponding cathode driving electrode 221) on the silicon-based driving substrate 20 to realize a bonding connection between the light-emitting carrier plate 10 and the silicon-based driving substrate 20.

The driving circuit layer 22 may provide a common voltage to a common cathode layer 133 through the cathode driving electrodes 221, and provide an operating voltage to the anode layer 131 of each of the sub-pixels 13 through a corresponding one of the anode driving electrodes 222, so as to drive the sub-pixels 13 to emit light.

The light-emitting carrier plate 10 may further include an encapsulation layer 16. The encapsulation layer 16 may be disposed on a side of each of the sub-pixels 13 away from the glass substrate 11 to encapsulate the sub-pixels 13. The structure and material of the encapsulation layer 16 are not limited and may be selected according to actual needs. A surface on a side of the encapsulation layer 16 away from the glass substrate 11 may be planarized.

In this embodiment, the encapsulation layer 16 may include a first encapsulation layer 161 and a second encapsulation layer 162. The first encapsulation layer 161 encapsulates the sub-pixels 13 and the isolation structures 14. The second encapsulation layer 162 is located on a side of the first encapsulation layer 161 away from the glass substrate 11. The first encapsulation layer 161 may be made of organic material, and the second encapsulation layer 162 may be made of inorganic material.

Please refer to FIG. 1 to FIG. 5. FIG. 5 is a layout schematic diagram of sub-pixels and connection through holes provided by a fourth embodiment of the present disclosure.

The sub-pixels 13 and the connection through holes 122 provided by a fourth embodiment of the present disclosure is basically similar in structure to the sub-pixels 13 and the connection through holes 122 provided by the first embodiment of the present disclosure. The difference is that each of the connection through holes 122 may be located in a corner of a rectangle of a corresponding one of the sub-pixels 13.

In this embodiment, in the direction parallel to the glass substrate 11, the sub-pixels 13 may be rectangular.

The sub-pixels 13 may be arranged in a matrix. Some of the isolation structures 14 may be partially overlapped with each other and have a common overlapping region. Each of the connection through holes 122 may be arranged in the overlapping region. Specifically, as shown in FIG. 5, each of the connection through holes 122 may be located in the overlapping region of four adjacent isolation structures 14 in the direction parallel to the glass substrate 11. That is, four isolation structures 14 share the same one of the connection through holes 122.

In some embodiments, the aperture of the connection through holes 122 may be 15 microns.

Compared with the sub-pixels 13 and the connection through holes 122 provided by the first embodiment of the present disclosure, the design of the connection through holes 122 in this embodiment may reduce the interval between the sub-pixels 13, thereby ensuring that the conductive portion 141 of each of the isolation structures 14 is electrically connected to the silicon-based driving substrate 20 through a corresponding one of the connection through holes 122 without reducing the area of the sub-pixels 13. Secondly, by increasing the aperture of the connection through holes 122 in different degrees, the preparation of the connection through holes 122 may be simplified, thereby improving process yield and further improving product reliability.

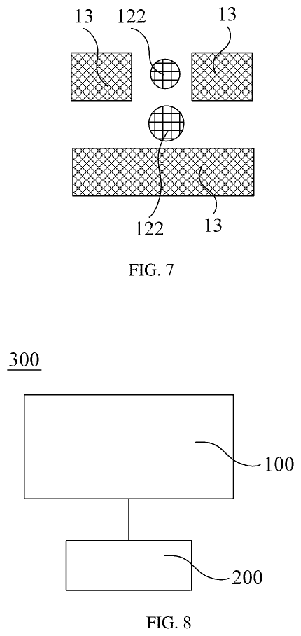

Please refer to FIG. 1 to FIG. 7. FIG. 6 is a layout schematic diagram of sub-pixels and connection through holes provided by a fifth embodiment of the present disclosure. FIG. 7 is a layout schematic diagram of sub-pixels and connection through holes provided by a sixth embodiment of the present disclosure.

Compared with the sub-pixels 13 and the connection through holes 122 provided by the fourth embodiment of the present disclosure, the sub-pixels 13 and the connection through holes 122 provided by the fifth embodiment of the present disclosure have a basically similar structure. The difference is that each of a part of the connection through holes 122 are located on the side of the rectangle, and each of another part of the connection through holes 122 are located at a corner of a rectangle of another corresponding one of the sub-pixels.

In this embodiment, every three of the sub-pixels 13 are combined to form a rectangular repeating unit. Repeating units are arranged in a matrix.

In every repeating unit, two sub-pixels 13 thereof are arranged side by side in a row direction of corresponding repeating unit and are arranged on a same side of other sub-pixel 13 in a column direction of corresponding repeating unit. In every repeating unit, three adjacent isolation structures 14 share a same connection through hole 122.

In every repeating unit, the same connection through hole 122 may be located at a corner of two rectangles formed by two sub-pixels 13 arranged side by side, and may be located on a side of a rectangle formed by other sub-pixel 13.

In some embodiments, the aperture of the connection through holes 122 may be 15 microns.

The design of the connection through holes 122 provided by this embodiment may also reduce the interval between the sub-pixels 13, ensure that each of the isolation structures 14 is electrically connected to the silicon-based driving substrate 20 through the corresponding one of the connection through holes 122 without reducing the area of the sub-pixels 13. Compared with the sub-pixels 13 and the connection through holes 122 provided by the fourth embodiment of the present disclosure, the arrangement of the sub-pixels 13 in this embodiment is different.

In other embodiments, in every repeating unit, some of the connection through holes 122 may be located on the side of the rectangle of the corresponding one of the sub-pixels 13, and some of the connection through holes 122 may be located at the corner of the rectangle of another corresponding one of the sub-pixels 13 (see FIG. 7). The arrangement of the sub-pixels 13 may be variable, and the arrangement of the connection through holes 122 may also be various. There is no restriction here, and it is selected according to actual needs.

Please refer to FIG. 8. FIG. 8 is a structural schematic diagram of an embodiment of a display device provided by the present disclosure.

A display device 300 is provided in the present disclosure. The display device 300 includes a mainboard 200 and a display panel 100 provided by the aforesaid embodiments. The display device 300 provided by the embodiments of the present disclosure may be an Active Matrix/Organic Light Emitting Diode (AMOLED).

The mainboard 200 may be electrically connected to the display panel 100. The mainboard 200 may be configured to transmit various signals to the display panel 100 to control the display panel 100 to display pictures. For example, a clock signal (CK), a low potential signal (Vss), a power supply voltage signal (VDD), and a data signal (Data) required by the driving circuit layer.

In the above embodiments, the descriptions of each embodiment have their own emphases. For the parts not elaborated in a certain embodiment, the relevant descriptions of other embodiments may be referred to.

The above are only the embodiments of the present disclosure, which do not limit the protection scope of the present disclosure. Any equivalent structure or equivalent process transformation made using the content of the specification and drawings of the present disclosure, directly or indirectly applied in other related technical fields, is similarly included within the protection scope of the present disclosure.

1. A display panel, comprising:
a silicon-based driving substrate;
a light-emitting carrier plate, bonded to the silicon-based driving substrate;
wherein the light-emitting carrier plate comprises:
a glass substrate, having a plurality of cathode through holes;
a pixel-defining layer, disposed on a side of the glass substrate away from the silicon-based driving substrate; wherein the pixel-defining layer has a plurality of pixel openings and a plurality of connection through holes;
a plurality of sub-pixels, each being disposed in the pixel opening; wherein each of the sub-pixel comprises an anode layer, a light-emitting layer, and a cathode layer sequentially stacked; and
a plurality of isolation structures, protruding from the pixel-defining layer and each being disposed on a side of a corresponding one of the sub-pixels; wherein each of the isolation structures comprises a conductive portion and a top structure sequentially stacked, and the cathode layer of each of the sub-pixels is lapped onto the conductive portion of a corresponding one of the isolation structures such that cathode layers of the sub-pixels are electrically connected together with each other;
wherein conductive portions of at least a part of the isolation structures are electrically connected to the silicon-based driving substrate through corresponding connection through holes and cathode through holes.

2. The display panel as claimed in claim 1, wherein a single one of the isolation structures is arranged corresponding to at least a corresponding one of the connection through holes.

3. The display panel according to claim 1, wherein some of the isolation structures share a same one of the connection through holes.

4. The display panel according to claim 3, wherein some of the isolation structures are partially overlapped with each other and have a common overlapping region; the same one of the connection through holes is disposed in the overlapping region.

5. The display panel according to claim 1, wherein each of the sub-pixels is rectangular in a direction parallel to the glass substrate;
each of the connection through holes is located on a side of a rectangle of a corresponding one of the sub-pixels.

6. The display panel according to claim 1, wherein each of the sub-pixels is rectangular in a direction parallel to the glass substrate;
each of the connection through holes is located at a corner of a rectangle of a corresponding one of the sub-pixels.

7. The display panel according to claim 6, wherein the sub-pixels are arranged in a matrix, and some of the isolation structures are partially overlapped with each other and have a common overlapping region.

8. The display panel according to claim 1, wherein each of the sub-pixels is rectangular in a direction parallel to the glass substrate;
each of a part of the connection through holes is located on a side of a rectangle of a corresponding one of the sub-pixels, and each of another part of the connection through holes is located at a corner of a rectangle of another corresponding one of the sub-pixels.

9. The display panel according to claim 8, wherein every three of the sub-pixels are combined to form a rectangular repeating unit, and repeating units are arranged in a matrix.

10. The display panel according to claim 9, wherein in every repeating unit, two sub-pixels thereof are arranged side by side in a row direction of corresponding repeating unit and are arranged on a same side of other sub-pixel in a column direction of corresponding repeating unit.

11. The display panel according to claim 10, wherein in every repeating unit, three adjacent isolation structures share a same connection through hole.

12. The display panel according to claim 10, wherein in every repeating unit, the same connection hole is located at a corner of two rectangles formed by two sub-pixels arranged side by side and located on a side of a rectangle formed by other sub-pixel.

13. The display panel according to claim 1, wherein the silicon-based driving substrate comprises:
a silicon substrate; and
a driving circuit layer, disposed on a side of the silicon substrate close to the light-emitting carrier plate.

14. The display panel according to claim 1, wherein the glass substrate further comprises a plurality of anode through holes, each thereof is spaced apart from a corresponding one of the cathode through holes with a distance, each anode layer is electrically connected to the silicon-based driving substrate through a corresponding one of the anode through holes; and
each of the anode through holes are disposed in one-to-one correspondence with a corresponding anode layer and is disposed adjacent to a corresponding one of the cathode through holes.

15. The display panel according to claim 14, wherein the light-emitting carrier plate further comprises a plurality of expansion electrodes, each thereof is located on a side of the glass substrate away from a corresponding one of the isolation structures, and each of the expansion electrodes comprises a cathode expansion electrode and an anode expansion electrode;
each of the conductive portions is electrically connected to the cathode expansion electrode of a corresponding one of the expansion electrodes through a corresponding connection through hole and a corresponding cathode through hole, and each of the cathode expansion electrodes is bonded to a corresponding one of cathode driving electrodes of the silicon-based driving substrate; and
the anode layer of each of the sub-pixels is electrically connected to the anode expansion electrode of a corresponding one of the expansion electrodes through a corresponding one of the anode through holes, and the anode expansion electrode of each of the expansion electrodes is bonded to a corresponding one of anode driving electrodes of the silicon-based driving substrate.

16. The display panel according to claim 1, wherein the top structure of each of the isolation structures extends beyond a corresponding one of the conductive portions in a direction parallel to the glass substrate, and an orthographic projection of the conductive portion of each of the isolation structures on the glass substrate covers an orthographic projection of a corresponding one of the connection through holes on the glass substrate.

17. A display device, comprising a mainboard and a display panel, wherein the display panel comprises:
a silicon-based driving substrate;
a light-emitting carrier plate, bonded to the silicon-based driving substrate;
wherein the light-emitting carrier plate comprises:
a glass substrate, having a plurality of cathode through hole;
a pixel-defining layer, disposed on a side of the glass substrate away from the silicon-based driving substrate; wherein the pixel-defining layer has a plurality of pixel openings and a plurality of connection through holes;
a plurality of sub-pixels, each being disposed in the pixel opening; wherein each of the sub-pixel comprises an anode layer, a light-emitting layer, and a cathode layer sequentially stacked; and
a plurality of isolation structures, protruding from the pixel-defining layer and each being disposed on a side of a corresponding one of the sub-pixels; wherein each of the isolation structures comprises a conductive portion and a top structure sequentially stacked, and the cathode layer of each of the sub-pixels is lapped onto the conductive portion of a corresponding one of the isolation structures such that cathode layers of the sub-pixels are electrically connected together with each other;
wherein conductive portions of at least a part of the isolation structures are electrically connected to the silicon-based driving substrate through corresponding connection through holes and cathode through holes.

18. The display device according to claim 17, wherein a single one of the isolation structures is arranged corresponding to at least a corresponding one of the connection through holes.

19. The display device according to claim 17, wherein some of the isolation structures share a same one of the connection through holes.

20. The display device according to claim 17, wherein some of the isolation structures are partially overlapped with each other and have a common overlapping region; the same one of the connection through holes is disposed in the overlapping region.
